(19) United States
(12) Patent Application Publication
(10) Pub. No.: US 2014/0024305 A1
(43) Pub. Date: Jan. 23, 2014

(54) MODULAR ENERGY-EFFICIENT AND SAFETY NETWORK CABINET

(71) Applicant: Xiaole Fu, Science & Technology City (CN)

(72) Inventor: Xiaole Fu, Science & Technology City (CN)

(73) Assignee: GUANGZHOU HOLDSTORM SCIENCE & TECHNOLOGY CO., LTD., Science & Technology City, Guangdong (CN)

(21) Appl. No.: 13/581,970

(22) PCT Filed: May 23, 2011
(86) PCT No.: PCT/CN2011/000887

§ 371 Date: Oct. 4, 2013

(30) Foreign Application Priority Data
Jan. 25, 2011 (CN) 201110026991.7

(51) Int. Cl. H05K 7/20

(52) U.S. Cl. CPC H05K 7/20736
USPC 454/184

(57) ABSTRACT

A modular energy-efficient and safety network cabinet comprises: at least one cabinet body; a main blast pipe, used to transfer air between an air-conditioner and the cabinet body defining a recycle way that the air is in from the bottom of the cabinet body and out from the top of the cabinet body; at least one tributary blast pipe, connected the main blast pipe and the cabinet body; a fire extinguisher, disposed above the cabinet body and full with inert-gas; an induction pipe, connecting the fire extinguisher and the cabinet body; a force draft fan, disposed under the cabinet body; a return fan, disposed above the cabinet body; an exhaust smoke valve, disposed above the return fan; a control system, used to control the temperature and humidity of the cabinet body and to put out a fire.

### FIELD OF THE INVENTION

The present invention relates to an intelligent modular energy-efficient and safety network cabinet.

### BACKGROUND OF THE INVENTION

At present, larger data centers and machine rooms are usually equipped with cabinets, the cooling capacity of the network cabinets and the fire-fighting gas should be set accordance with the area and volume of the room. However, there are the following shortcomings: (1) to meet the needs of the machines, the air-conditioner should be precisely in constant temperature and constant humidity state, and since the area of the room is larger, the needs of the cooling capacity is too large to make a waste; (2) to meet the needs of putting out the fire of the whole room, the fire-fighting gas should be sufficient and this will make the cost high; (3) when a fire alarm occurs caused by a smoke sensor and temperature sensor, inert-gas will be ejected to the whole room in a rush, causing all equipment to be out of service or even scrapped and causing network failure and data loss, the worse situation is that when people are not aware of the damage, it may cause people to die of asphyxiation.

### SUMMARY OF THE INVENTION

One object of the present invention is to provide an intelligent modular energy-efficient and safety network cabinet. To achieve the aim, the following technical schemes are applied.

A modular energy-efficient and safety network cabinet comprises: at least one cabinet body; a main blast pipe, used to transfer air between an air-conditioner and the cabinet body; at least one tributary blast pipe, connected to the main blast pipe and the cabinet body; a fire extinguisher, disposed above the cabinet body and full with inert-gas; an induction pipe, connecting the fire extinguisher and the cabinet body; a force draft fan, disposed under the cabinet body; a return fan, disposed above the cabinet body; an exhaust smoke valve, disposed above the return fan; a line inlet and outlet for strong-and-weak current, disposed at the bottom of the cabinet body; a control system, used to control the temperature and humidity of the cabinet body and to put out a fire.

In accordance with the present invention, the equipment is inside the cabinet. Only the inner space of the cabinet is taken into consideration in order to achieve the constant temperature and humidity working conditions. Common air-conditioners are used for the outside space of the cabinet, and this can decrease the total power consumption of the air conditioners, which saves energy. Otherwise, the firefighting gas depends on the inner space of each independent cabinet, when the common fire extinguisher is used for the outside space of the cabinet, so the total consumption volume of firefighting gas is reduced and the volume of reserve firefighting gas is decreased, what is more important is that this avoids the whole firefighting gas being released at the same time to cause all equipment to be out of service or even scrapped and causing network failure and data loss, or other unpredictable effects. The worse situation is that when people are not aware of the damage, it may cause the people to die of asphyxiation, so the present invention is not only energy-saving, but also safe.

### DESCRIPTION OF THE DRAWINGS

In order to better illustrate the invention, preferred embodiments combined the manual illustrated is following.

FIG. 1 is the structure stereogram of part of the intelligent modular energy-efficient and safety network cabinet in accordance with the present invention.

FIG. 2 is the schematic diagram of the intelligent modular energy-efficient and safety network cabinet mounted on the floor in accordance with the present invention, which defines a way to recycle air in from the bottom and out from the top.

### DETAILED DESCRIPTION OF ILLUSTRATED EMBODIMENTS

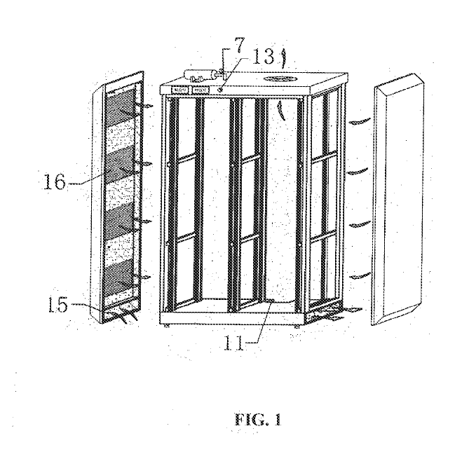

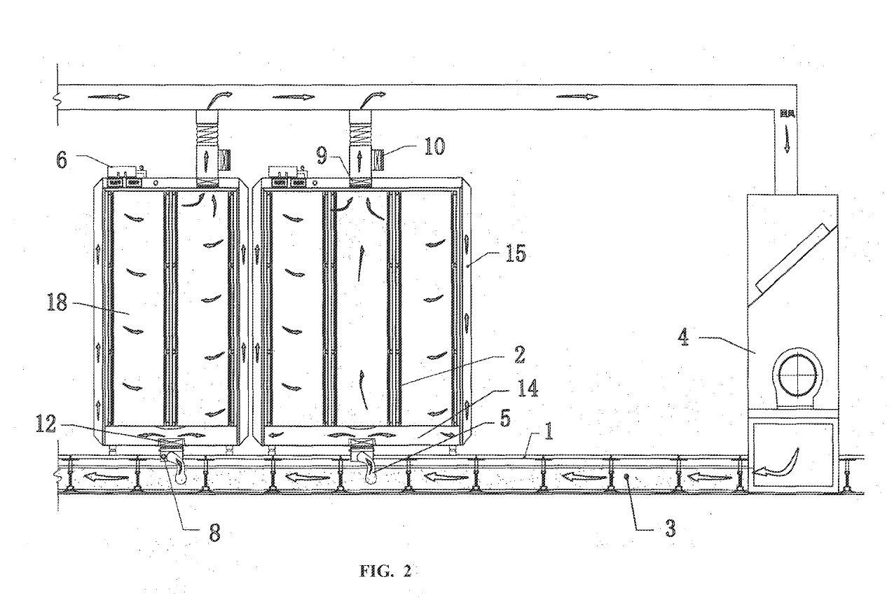

Referring to FIG. 1 and FIG. 2, an intelligent modular energy-efficient and safety network cabinet, located on the floor 1 of the room, includes:

(a) at least one cabinet body 2, designed according to match equipment, that is fully detachable when combined with a standard manufacture unit, it may be specially manufactured according to the actual equipment;
(b) a main blast pipe 3, used to transfer air between an air-conditioner and the cabinet body 2;
(c) at least one tributary blast pipe 5, connected the main blast pipe 3 and the cabinet body 2;
(d) a fire extinguisher 6, disposed above the cabinet body 1 and full with inert-gas;
(e) an induction pipe 7, connecting the fire extinguisher 6 and the cabinet body 2;
(f) a force draft fan 8, disposed under the cabinet body 2;
(g) a return fan 9, disposed above the cabinet body 2;
(h) an exhaust smoke valve 10, disposed above the return fan 9;
(i) a line inlet and outlet 11 for strong-and-weak current, disposed at the bottom of the cabinet body 2;
(j) a detachable cover, and used to avoid cold air flowing away from the inside to the outside of the cabinet body;
(k) a control system, used to control the temperature and humidity of the cabinet body 2 and to put out fire.

Wherein the control system comprises a temperature sensor, a humidity sensor, a smoke sensor, and other elements (not shown in figures). Both a thermometer and a hygrometer are disposed outside the cabinet body 2 and are connected with the control system, so the temperature and humidity of the cabinet body 2 are known.

Wherein an air guide device 12 is disposed on the junction of the tributary blast pipe 5 and the cabinet body 2, and the force draft fan 8 is under the air guide device 12.

When a fire alarm occurs in one cabinet body 2, the control system lets the corresponding force draft fan 8 and return fan 9 close automatically, and fire extinguisher 6 will emit inert-gas and ensure the pressure in the cabinet body. Putting out a fire inside one or more special cabinet body 2, avoids the whole firefighting gas breaking out in a flash that may cause damage to other cabinet bodies and the threat of death by asphyxia.

A fire valve 13 is disposed on the side of the fire extinguisher 6, and the fire extinguisher 6 is able to control the ejection of inert-gas manually or automatically. Until the fire alarm is over, an exhaust smoke valve 10 above the return fan 9 will work during a set time in order to discharge gas and smoke,

A bottom air intake duct 14 is disposed at the bottom of the cabinet body 2 connected to the tributary blast pipe 5, and two side air intake ducts 15, which is connected to the bottom air intake duct 14, comprising air supply louvers 16, used to transfer air into the cabinet body 2, disposed on both sides of the cabinet body 2 respectively. The air from the air conditioner passes through the main blast pipe 3 at first, and then through the tributary blast pipe 5, and then through the bottom air intake duct 14 and side air-intake ducts 15, and then through the air supply louvers 16 into the cabinet body 2.

Furthermore, the total supply air volume and return air volume are controlled respectively by the force draft fan 8 and the return fan 9, however, the force draft fan 8 and the return fan 9 are adjusted automatically by the control system according to the temperature and humidity inside the cabinet body 2, thus the temperature and humidity inside the cabinet body 2 will be kept at an ideal condition.

Two gas pressure relief openings, having a pressure release valve mounted thereon, are formed on a sheathing of the line inlet and outlet at the bottom of the cabinet body 2, which prevents damage to the equipment due to very large pressure inside the cabinet body 2 when the inert-gas breaks out.

In the present invention, the independent control of power supply and point-to-point firefighting make the cabinet bodies 2 safe and energy-efficient, for it is able to automatically cut off its own power in case of fire, and do not impact the work of other cabinet bodies. In such a case, the fire extinguisher starts working and puts out the fire just in a special cabinet body. Thus, it can reduce the gas consumption and improve the accuracy. And also, it can avoid all the gas being sprayed in one time and to avoid waste. In addition, it prevents all the equipment from being out of service or scrapped, the network from denial of service and the danger to people of death from asphyxiation.

The cabinet body 2 is mounted with a fireproof and heat insulation glass door 18, which makes it convenient to maintain the equipment and observe the working condition. At the bottom of the cabinet body 2, there are also line inlet and outlet. The temperature and the humidity, fire extinguisher and linked system for power supplies are all intelligently and automatically controlled, accompanied with the essential auxiliary manual control. The cabinet body 2 is mounted by combination of the separable standard modules, so that it can be maintained and transported conveniently.

In accordance with the present invention, the equipment is inside cabinet body 2. Only the space of the cabinet body is taken into consideration to set the constant temperature and humidity. For the outside space of the cabinet body 2, the common air conditioners may be chosen, and this makes the total power of the air conditioners 4 efficiently decreased and saves energy. In addition, the firefighting gas depends on the space of each cabinet body 2, in order to minimize the fire area and to put out the fire accurately. And for the outside space of the cabinet body 2, common fire extinguishers may be chosen, so the volume of reserve gas is decreased, what's more, this avoids waste of the gas being released in one time and the danger to people. Therefore, the modular energy-efficient safety cabinet is high efficient, energy saving, safe and has a lower cost.

While the present invention has been illustrated by the above description of the preferred embodiments thereof, while the preferred embodiments have been described in considerable detail, it is not intended to restrict or in any way limit the scope of the appended claims to such details. Other advantages and modification within the spirit and scope of the present invention will readily appear to those skilled in the art. Therefore, the present invention is not limited to the specific details and the illustrative examples shown and described.

What is claimed is:

1. A modular energy-efficient and safety network cabinet, comprising:
at least one cabinet body;
a main blast pipe, used to transfer air between an air-conditioner and the cabinet body;
at least one tributary blast pipe, connected to the main blast pipe and the cabinet body;
a fire extinguisher, disposed above the cabinet body and full with inert gas;
an induction pipe, connecting the fire extinguisher and the cabinet body;
a force draft fan, disposed under the cabinet body;
a return fan, disposed above the cabinet body;
an exhaust smoke valve, disposed above the return fan;
a line inlet and outlet for strong-and-weak current, disposed at the bottom of the cabinet body;
a gas pressure relief opening, disposed at the bottom of the cabinet body;
a control system, used to control the temperature and humidity of the cabinet body and to put out fire.

2. The modular energy-efficient and safety network cabinet of claim 1, wherein an air guide device is disposed on the junction of the tributary blast pipe and the cabinet body, and the force draft fan is under the air guide device.

3. The modular energy-efficient and safety network cabinet of claim 1, wherein a bottom air intake duct is disposed at the bottom of the cabinet body connected to the tributary blast pipe, and two side air-intake ducts, which is connected to the bottom air-intake duct, comprising air supply louvers used to transfer air into the cabinet body, are disposed on both sides of the cabinet body respectively.

4. The modular energy-efficient and safety network cabinet of claim 1, wherein the fire extinguisher comprises a fire valve.

5. The modular energy-efficient and safety network cabinet of claim 1, wherein the control system comprises a temperature sensor, a humidity sensor, and a smoke sensor.

6. The modular energy-efficient and safety network cabinet of claim 1, wherein the cabinet body is mounted with a fireproof and heat insulation glass door.

7. The modular energy-efficient and safety network cabinet of claim 1, wherein a line inlet and outlet for strong-and-weak current is disposed at the bottom of the cabinet body, a gas pressure relief opening is disposed at the bottom of the cabinet body.

8. The modular energy-efficient and safety network cabinet of claim 1, wherein both a thermometer and a hygrometer are disposed outside the cabinet body and are connected with the control system.

9. The modular energy-efficient and safety network cabinet of claim 1, wherein the temperature, the humidity, the fire extinguisher, and the linked system for power supplies are all intelligently and automatically controlled, accompanied with the essential auxiliary manual control.

10. The modular energy-efficient and safety network cabinet of claim 1, wherein the cabinet body is mounted by combination of separative standard modules.
